(19) United States
(12) Patent Application Publication
(10) Pub. No.: US 2026/0180589 A1
(43) Pub. Date: Jun. 25, 2026

(54) FLASH SUCCESSIVE APPROXIMATION REGISTER ANALOG-TO-DIGITAL CONVERTER WITH ERROR CORRECTION

(71) Applicant: Renesas Electronics America Inc., Milpitas, CA (US)

(72) Inventors: Ralph David MOORE, JR., Greensboro, NC (US); Christopher MICHALSKI, Milpitas, CA (US)

(73) Assignee: Renesas Electronics America Inc., Milpitas, CA (US)

(21) Appl. No.: 18/989,640

(22) Filed: Dec. 20, 2024

(51) Int. Cl. H03M 1/06

(52) U.S. Cl. CPC H03M 1/0604

(57) ABSTRACT

Systems and methods for analog-to-digital conversion are described. A device can include a successive approximation register (SAR) analog-to-digital converter (ADC) and a flash ADC with a fractional bit resolution. The flash ADC can determine a digital code that encodes a voltage range of an input voltage, provide redundancy for digital error correction and output the digital code to the SAR ADC. The SAR ADC can decode the digital code to obtain a first set of bit values of a set of most significant bits (MSBs) of a digital output that is a digital representation of the input voltage, determine a second set of bit values of a set of least significant bits (LSBs) of the digital output, and generate the digital output based on the first set of bit values and the second set of bit values.

### BACKGROUND

The present disclosure relates in general to semiconductor devices. More specifically, the present disclosure relates to flash successive approximation register analog-to-digital converter (ADC) with error correction.

Electronic devices and electronic systems operate predominantly in the digital domain. Digital signal processing, data transmission and data storage are a few application examples. Driven by greater demands from high performance applications, the speed and complexity of interfacing with analog signals are rapidly increasing. Analog signals can be converted to digital signals to take advantage of the huge scale of digital processing platforms, consequently, high-performance analog-to-digital converters are critical design system function.

### SUMMARY

In one embodiment, a semiconductor device for converting an analog signal into a digital signal is generally described. The semiconductor device can include a successive approximation register (SAR) analog-to-digital converter (ADC) and a flash ADC with a fractional bit resolution. The flash ADC can determine a digital code that encodes a voltage range of an input voltage, provide redundancy for digital error correction and output the digital code to the SAR ADC. The SAR ADC can decode the digital code to obtain a first set of bit values of a set of most significant bits (MSBs) of a digital output that is a digital representation of the input voltage, determine a second set of bit values of a set of least significant bits (LSBs) of the digital output, and generate the digital output based on the first set of bit values and the second set of bit values.

In one embodiment, a system for converting an analog signal into a digital signal is generally described. The system can include a first device configured to output an analog signal, a second device, and an analog-to-digital converter (ADC). The ADC can include a successive approximation register (SAR) ADC and a flash ADC with a fractional bit resolution. The flash ADC can be configured to determine a digital code that encodes a voltage range of an input voltage sampled from the analog signal. The flash ADC can be further configured to provide redundancy for digital error correction. The flash ADC can be further configured to output the digital code to the SAR ADC. The SAR ADC can be configured to decode the digital code to obtain a first set of bit values of a set of most significant bits (MSBs) of a digital output that is a digital representation of the input voltage. The SAR ADC can be further configured to determine a second set of bit values of a set of least significant bits (LSBs) of the digital output. The SAR ADC can be further configured to generate the digital output based on the first set of bit values and the second set of bit values. The SAR ADC can be further configured to output the digital output to the second device.

In one embodiment, a method for converting an analog signal into a digital signal is generally described. The method can include determining, by a flash analog-to-digital converter (ADC) in an ADC, a digital code that encodes a first set of bit values of a digital output that is a digital representation of an input voltage. The digital output can include a set of most significant bits (MSBs) and a set of least significant bits (LSBs), and the first set of bit values are bit values of the set of MSBs. The method can further include providing, by the flash ADC in the ADC, redundancy for digital error correction. The method can further include outputting, by the flash ADC in the ADC, the digital code to a successive approximation register (SAR) ADC in the ADC. The method can further include decoding, by the SAR ADC in the ADC, the digital code to obtain the first set of bit values. The method can further include determining, by the SAR ADC in the ADC, a second set of bit values of the digital output, wherein the second set of bit values are bit values of the set of LSBs. The method can further include generating, by the SAR ADC in the ADC, the digital output based on the first set of bit values and the second set of bit values.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 is a diagram showing an example system that can implement flash successive approximation register analog-to-digital converter with error correction in one embodiment.

FIG. 2 is a diagram showing an example implementation of a flash successive approximation register analog-to-digital converter with error correction in one embodiment.

FIG. 3 is a diagram showing an example error correction flash ADC that can be used for implementing flash successive approximation register analog-to-digital converter with error correction in one embodiment.

FIG. 4 is a diagram showing a search sequence in an example implementation of flash successive approximation register analog-to-digital converter with error correction in one embodiment.

FIG. 5 is a flowchart of an example process that can implement flash successive approximation register analog-to-digital converter with error correction in one embodiment.

### DETAILED DESCRIPTION

In the following description, numerous specific details are set forth, such as particular structures, components, materials, dimensions, processing steps and techniques, to provide an understanding of the various embodiments of the present application. However, it will be appreciated by one of ordinary skill in the art that the various embodiments of the present application may be practiced without these specific details. In other instances, various structures or processing steps have not been described in detail to avoid obscuring the present application.

Unlike digital signal processing, analog and mixed-signal performance does not scale according to Moore's law, and in many cases, the limiting factor of overall system performance. Increasing the challenge facing data converters, the positive power supply voltage Vcc of advanced Complementary metal-oxide-semiconductor (CMOS) processes are operating at sub-1V levels (e.g., lower than one volt), while the noise and interference magnitude remains unchanged. This significantly decreases the signal-to-noise ratio. The devices, systems and methods described in the present disclosure can address the need for a high-speed analog-to-digital converter (ADC) architecture.

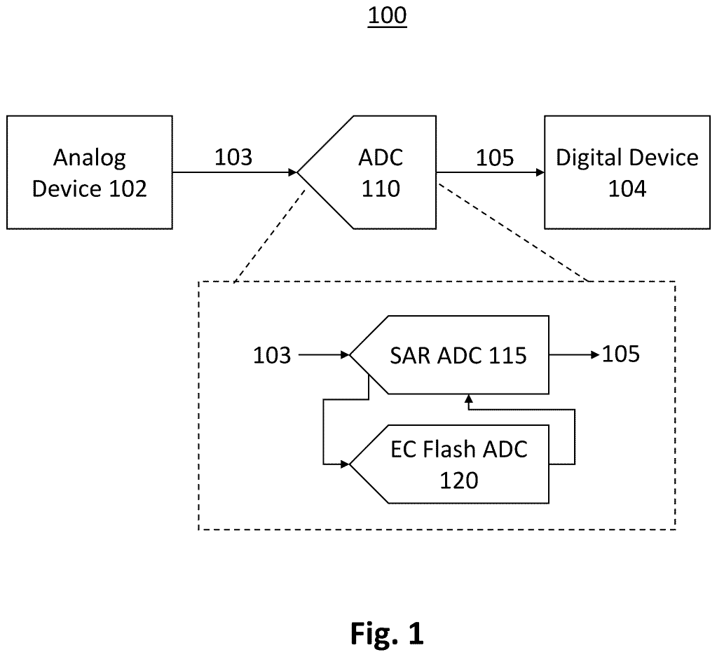

FIG. 1 is a diagram showing an example system that can implement flash successive approximation register analog-to-digital converter with error correction in one embodiment. System 100 can be implemented by one or more semiconductor devices. System 100 can be a conversion system for converting an analog signal into a digital signal. System 100 can include at least an analog device 102, a digital device 104, and an analog-to-digital converter (ADC) 110. ADC 110 can be a part of a microcontroller. Analog device 102 can output an analog signal 103. ADC 110 can be configured to convert analog signal 103 into a digital signal 105 and can send digital signal 105 to digital device 104. Digital signal 105 can be a digital representation of analog signal 103. System 100 can be implemented for various applications. For example, analog device 102 can be a sensor device that measures parameters such as voltage signals and digital device 104 can include memory devices that store digital code, and ADC 110 can convert the voltage signals into digital code that can be stored in the memory devices.

In an aspect, there are different ADC architectures, such as successive approximation register (SAR) ADCs, Flash ADCs, or hybrid ADCs that includes both SAR ADCs and Flash ADCs. SAR ADCs can be used for medium to high resolution conversions due to lower power consumption and die area, as compared to other ADC architectures. However, SAR ADCs have speed limitations due to the requirement of using a clock cycle for each bit resolution. This shortcoming prevents SAR ADCs from being utilized for applications that require high speed conversion. Further, to convert a single sampled voltage into a N-bit digital code (N-bit resolution), a SAR ADC performs a sequential binary search. A binary search can be a search for the sampled voltage in a voltage range. Based on where the sampled voltage is in the voltage range, the binary search result is used for detecting a binary value (e.g., a bit value such as zero or one) to be assigned to a bit in the N-bit digital code. A SAR ADC performs the binary search in a sequential manner, bit-by-bit from the most significant bit (MSB) to the least significant bit (LSB), to detect the correct bit value (0 or 1) for each bit in the N-bit digital code. If there is a detection error in the MSB, then the final N-bit code will also be incorrect. To address such detection errors, SAR ADCs can be implemented with redundancy, such as extra comparison cycles, which causes the number of comparison steps to be greater than the bit resolution. Using the extra comparison cycles, the SAR DAC can serially test a given MSB input signal twice, which is a process that can be referred to as redundancy. The redundant search can yield the correct result for the MSB and will result in the correct output providing no errors occur in subsequent compare cycles. However, redundancy in SAR DACs can slow down the conversion and can incur voltage range penalty. For example, for a 4-bit resolution, the conversion of a sampled voltage with MSB redundancy can take 5 cycles to complete, and the voltage search range in cycles subsequent to the MSB cycle can extend beyond the initial voltage search range.

A Flash ADC uses a linear voltage ladder with a plurality of comparators (e.g., 2^{N}−1 comparators) to compare an input voltage to successive reference voltages. The linear voltage ladder includes multiple resistors or capacitors that divide a reference voltage into different reference voltages for the comparators. Each comparator compares the input voltage to its respective divided reference voltage. The comparator outputs are fed into a digital encoder that converts the comparator outputs inputs into the N-bit digital code. Flash ADC can convert at higher speed when compared to SAR ADC due to performing the comparisons in parallel. Flash ADCs can also be relatively simpler to implement when compared to SAR ADCs. For example, the parallel comparators can be the analog components in a flash ADC and the rest of the components in the flash ADC are digital logic components. Further, flash ADCs may not require a sample and hold circuit at the input of the ADC since the parallel comparators can function as sampling devices. However, the analog comparators in flash ADCs increase as the bit resolution increases, hence the size, power consumption, and cost of the comparators becomes infeasible as the resolution increases.

Some conventional ADC architectures utilize a hybrid approach by combining a flash ADC with a SAR ADC, which can be referred to as a Flash-SAR ADC. The Flash-SAR ADC can provide the parallel structure of a flash ADC to shorten the number of comparison cycles of the SAR ADC, and the flash ADC can reduce the search window of the MSB of the SAR ADC. However, conventional flash-SAR ADCs still utilize the MSB redundancy for error correction, hence the extra comparison cycles are still being added for error correction as in SAR ADCs.

To mitigate the shortcomings of various ADC architectures described above, ADC 110 described herein can include components that implement an error correction (EC) flash-SAR ADC architecture. The EC flash-SAR ADC architecture is a hybrid ADC architecture that optimizes a flash-SAR ADC by combining an EC flash ADC 120 with a SAR ADC 115. The EC flash ADC 120 in the EC flash-SAR ADC architecture can determine bit values and redundancy for a number of MSBs, such as P MSBs, in parallel while the SAR ADC 115 in ADC 110 can perform binary search for the rest of the bits, such as Q bits (least significant bits (LSBs)), where N=P+Q. For example, for N=4, the EC flash ADC 120 can determine a bit value for one MSB (P=1) and provide redundancy in parallel using one cycle while the SAR ADC 115 can perform binary search for the other three bits or three LSBs (Q=3) using three cycles, completing the conversion in four cycles. The EC flash-SAR ADC architecture can be scalable to different resolutions. For example, for N=18, the EC flash ADC 120 can simultaneously resolve three MSBs (P=3) and provide redundancy using one cycle while the SAR ADC 115 can perform binary search for the other fifteen bits or fifteen LSBs (Q=15). Thus, by using EC flash ADC 120, ADC 110 can increase conversion speed and reduce search voltage range and does not require extra comparison cycles for redundancy, while performing high resolution conversion by utilizing the SAR ADC 115.

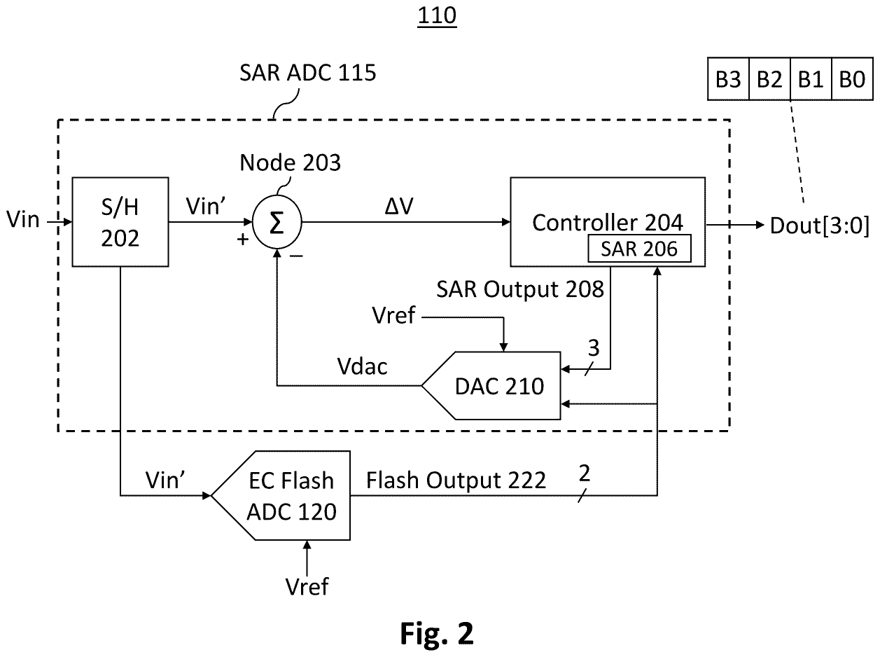

FIG. 2 is a diagram showing an example implementation of a flash successive approximation register analog-to-digital converter with error correction in one embodiment. Descriptions of FIG. 2 can reference components shown in FIG. 1. In an embodiment shown in FIG. 2, ADC 110 can include a SAR ADC 115 and an EC flash ADC 120. SAR ADC 115 can include a sample and hold (S/H) circuit 202, a controller 204, a SAR 206 and a digital-to-analog converter (DAC) 210. In some embodiments, sample and hold circuit 202 may be implemented as an implicit function within SAR ADC 115 instead of being an explicit circuit (e.g., a separate piece of hardware). EC flash ADC 120 can be configured to perform redundancy, such as determining or checking a bit values for the same bit twice. Controller 204 and SAR 206 can be integrated on the same circuit board. SAR 206 can be a plurality of storage devices, such as registers. Controller 204 can include one or more semiconductor devices implementing, for example, a microcontroller including hardware. Controller 204 can include, for example, a processor, central processing unit (CPU), field-programmable gate array (FPGA) or any other circuitry that is configured to control and operate various aspects of ADC 110.

To implement the EC flash-SAR ADC architecture described in the present disclosure, EC flash ADC 120 can be a flash ADC having a fractional bit resolution. In the embodiment shown in FIG. 2, ADC 110 is a 4- bit ADC configured to convert an input voltage Vin of analog signal 103 into a 4-bit digital code Dout[3:0] (e.g., digital signal 105). When ADC 110 is a 4-bit ADC, SAR ADC 206 is a 3-bit SAR ADC and EC flash ADC 120 is a 1.5-bit flash ADC (e.g., 1-bit flash ADC with 0.5 bit precision). The 1.5-bit EC flash ADC 120 can determine the bit value of the MSB, which is bit B3, of Dout and also perform redundancy on the MSB B3. The 3-bit SAR ADC 206 can perform binary search to determine the bit values for the rest of the bits, such as bits B2, B1, B0 of Dout.

ADC 110 can convert input voltage Vin into Dout by operating EC flash ADC 120 in one clock cycle to resolve one or more MSBs in parallel, and operating SAR ADC 115 to perform sequential binary search for one or more LSBs. For the 4-bit ADC shown in FIG. 2, EC flash ADC 120 can use one cycle to resolve one MSB B3, and SAR ADC 115 can use three cycles to perform binary search for three LSBs, which is a total of four clock cycles. A clock cycle can be a period of time, and the four clock cycles may span the same amount of time or different amount of time. In the first clock cycle, EC flash ADC 120 can determine a bit value for the MSB B3. In the second to fourth clock cycles, SAR ADC 115 can perform binary search for the bits B2, B1, B0, sequentially.

Sample and hold circuit 202 can receive input voltage Vin. Sample and hold circuit 202 can sample the input voltage Vin and output the sampled voltage Vin′ to EC flash ADC 120 and to a node 203. Vin′ and a DAC output Vdac can be combined at node 203. In one embodiment, Node 203 can be implemented by a comparator that can subtract Vdac from Vin′ to generate a voltage difference ΔV. Voltage difference ΔV can be updated at each clock cycle during the binary search performed by SAR ADC 115, and the updated ΔV provided to controller 204. Controller 204 can control operations of SAR ADC 115 based on voltage difference ΔV to perform binary search for bits B2, B1, B0. In the first clock cycle, controller 204 can suspend operations of SAR ADC 115 to allow EC flash ADC 120 to determine the bit value for MSB B3. By way of example, despite receiving voltage difference ΔV in the first clock cycle, controller 204 may not control SAR ADC 115 to perform any binary search until receiving an output from EC flash ADC 120.

In the first clock cycle, EC flash ADC 120 can compare sampled voltage Vin′ with different reference voltages, in parallel, that are based on a reference voltage Vref, and encode the comparison results to generate a flash output 222. Thus, EC flash ADC can perform error correction by performing the parallel comparisons since the parallel comparisons can be considered as redundant comparisons. In an aspect, a 1.5-bit flash ADC can classify sampled voltage Vin′ into three voltage ranges or voltage regions. The first voltage region is from −Vref to −Vref/4, the second voltage region is from −Vref/4 to +Vref/4, and the third voltage region is from Vref/4 to Vref. Flash output 222 can be a digital code encoding an indication of one of the three voltage region Vin′ falls into. Flash output 222 can be provided to DAC 210 and controller 204. Controller 204 can decode flash output 222 to determine a binary value that corresponds to the voltage region indicated by flash output 222, and can assign the determined binary value to MSB B3, and store the assigned binary value in a first register among SAR 206 that corresponds to MSB B3. In response to assigning a binary value to the MSB B3, controller 204 can resume operations of SAR ADC 115 to begin the second clock cycle.

In the second clock cycle, controller 204 can set a second register among SAR 206 corresponding to bit B2 to a default value of one. Controller 204 can also set a third register and a fourth register among SAR 206, corresponding to bits B1, B0, respectively, to zero. Controller 204 can generate a SAR output 208 that can be a 3-bit digital code “100”, representing the values set to the second, third, fourth registers. SAR output 208 can be provided to DAC 210. In the first clock cycle, flash output 222 was already provided to DAC 210. DAC 210 can be configured to decode flash output 222 to determine a binary value of MSB B3, and combine the determined binary value with the SAR output 208 to form a 4-bit digital code. DAC 210 can convert this 4-bit digital code into the DAC output Vdac. By way of example, DAC 210 can divide the reference voltage Vref by a value encoded in the 4-bit digital code, formed by flash output 222 and SAR output 208, to generate Vdac. If Vin′ is greater than Vdac, or voltage difference ΔV is positive (e.g., greater than zero), then controller 204 can maintain the value of the second register, which is set to one, and assign binary one to the bit B2 in the second clock cycle. If Vin′ is less than Vdac, or voltage difference ΔV is negative (e.g., greater than zero), then controller 204 can change the value of the second register, which is set to one, to zero and assign binary zero to the bit B2 in the second clock cycle.

In the third clock cycle, controller 204 can set the third register to one, and set the fourth register to zero. Controller 204 can update the SAR output 208 to a 3-bit digital code representing the values set to the second, third, fourth registers. If the second register was maintained in the second clock cycle, then the updated SAR output 208 is “110”. If the second register was changed to zero in the second clock cycle, then the updated SAR output 208 is “010”. The bit value decoded from flash output 222 (received by DAC 210 in the first clock cycle) and the updated SAR output 208 can be combined at DAC 210 to form an updated 4-bit digital code, and DAC 210 can convert this updated 4-bit digital code to update the DAC output Vdac. If Vin′ is greater than the updated Vdac, or voltage difference ΔV is greater than zero, then controller 204 can maintain the value of the third register, which is set to one, and assign binary one to the bit B1 in the third clock cycle. If Vin′ is less than Vdac, or voltage difference ΔV is negative (e.g., greater than zero), then controller 204 can change the value of the third register, which is set to one, to zero and assign binary zero to the bit B1 in the third clock cycle.

In the fourth clock cycle, controller 204 can set the fourth register to one, and set the fourth register to zero. Controller 204 can update the SAR output 208 to a 3-bit digital code representing the values set to the second, third, fourth registers. The bit value decoded from flash output 222 (received by DAC 210 in the first clock cycle) and the updated SAR output 208 can be combined at DAC 210 to form an updated 4-bit digital code, and DAC 210 can convert this updated 4-bit digital code to update the DAC output Vdac. If Vin′ is greater than the updated Vdac, or voltage difference ΔV is greater than zero, then controller 204 can maintain the value of the fourth register, which is set to one, and assign binary one to the LSB B0 in the fourth clock cycle. If Vin′ is less than Vdac, or voltage difference ΔV is negative (e.g., greater than zero), then controller 204 can change the value of the fourth register, which is set to one, to zero and assign binary zero to the LSB B0 in the fourth clock cycle. Once all the bits in Dout are assigned with a binary value, the conversion is completed the ADC 110 can output Dout to digital device 104.

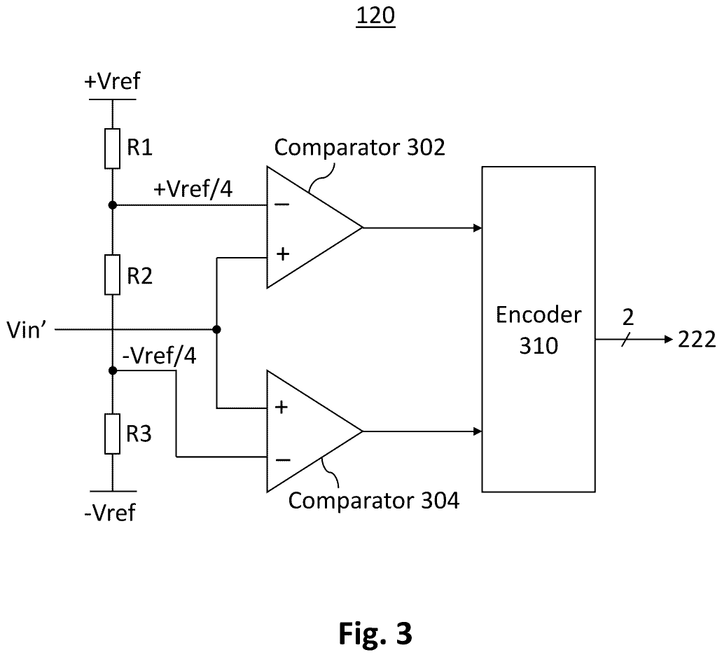

FIG. 3 is a diagram showing an example error correction flash ADC that can be used for implementing flash successive approximation register analog-to-digital converter with error correction in one embodiment. Descriptions of FIG. 2 can reference components shown in FIG. 1 to FIG. 2. In an example shown in FIG. 3, EC flash ADC120 is a 1.5-bit flash ADC. EC flash ADC120 can include a comparator 302, a comparator 304, an encoder 310, and a voltage ladder formed by a plurality of resistors R1, R2, R3. The arrangement of the resistors R1, R2, R3 can implement voltage dividers that divide a voltage range from −Vref to +Vref into three different voltage ranges. The embodiment in FIG. 3 utilized resistors to divide the reference voltage range, but there can be other implementations where capacitors are used for dividing the reference voltage range.

As mentioned above, the first voltage region is from −Vref to −Vref/4, the second voltage region is from −Vref/4 to +Vref/4, and the third voltage region is from Vref/4 to Vref. As a result of dividing the voltage range from −Vref to +Vref, comparator 302 can compare the sampled voltage Vin′ with +Vref/4 and comparator can compare the sampled voltage Vin′ with −Vref/4. The output of comparator 302 can indicate whether Vin′ is greater than or less than +Vref/4, and the output of comparator 304 can indicate whether Vin′ is greater than or less than −Vref/4.

Encoder 310 can be configured to receive the outputs from comparators 302, 304 and encode the outputs from comparators 302, 304 into flash output 222. By way of example, encoder 310 can encode the outputs from comparators 302, 304 into three distinct 2-bit digital code representing the three voltage regions. For example, “00” can represent the first voltage region from −Vref to −Vref/4, “01” can represent the second voltage region from −Vref/4 to +Vref/4, and “10” can represent the third voltage region is from Vref/4 to Vref.

In one embodiment, since the first clock cycle is performed by EC flash ADC 120 and the second to fourth clock cycles are performed by SAR ADC 115, the reference voltages being used by the two different ADCs can be different despite the two ADCs receiving the same reference voltage Vref. By way of example, the for the 1.5-bit flash ADC shown in FIG. 3, the reference voltages being used by EC flash ADC 120 are −Vref/4 and +Vref/4, but the reference voltages being used by SAR ADC 115 can be different from −Vref/4 and +Vref/4 and the reference voltages being used by SAR ADC 115 can vary depending on the sequential binary searches performed by SAR ADC 115.

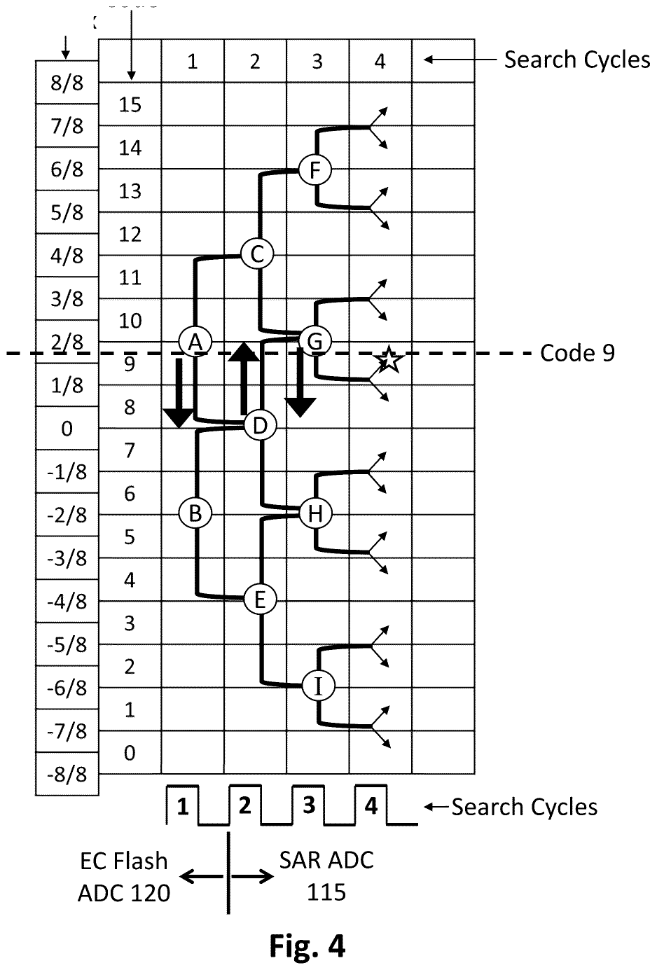

FIG. 4 is a diagram showing a search sequence in an example implementation of flash successive approximation register analog-to-digital converter with error correction in one embodiment. Descriptions of FIG. 4 can reference components shown in FIG. 1 to FIG. 3. FIG. 4 shows a search sequence performed by ADC 110 described herein for converting analog signal 103 into a 4-bit digital code (digital signal 105) using four clock cycles. In the first clock cycle, EC flash ADC 120 can determine the MSB B3 (see FIG. 2).

In the first clock cycle, EC flash ADC 120 can compare Vin′ with −Vref/4 (or −Vref× 2/8) and compare Vin′ with +Vref/4 (+Vref× 2/8). A comparison A in FIG. 3 is the comparison of Vin′ with +Vref/4 (by comparator 302) and a comparison B in FIG. 3 is the comparison of Vin′ with −Vref/4 (by comparator 304). EC flash ADC 120 can output the comparison values A and B as flash output 222 to allow controller 204 to determine the bit value for MSB B3.

In the second clock cycle, SAR ADC 115 can perform one of comparisons C, D, E depending on a search result from comparisons A and B. In the example shown in FIG. 3, the result from comparison A leads to comparison D. Therefore, in the second clock cycle, SAR ADC 115 will perform comparison D to determine the bit value for bit B2.

In the third clock cycle, SAR ADC 115 can perform one of comparisons F, G, H depending on a search result from the second clock cycle. In the example shown in FIG. 3, the result from the second clock cycle leads to comparison G. Therefore, in the third clock cycle, SAR ADC 115 will perform comparison G to determine the bit value for bit B1.

In the fourth clock cycle, SAR ADC 115 can perform a comparison depending on a search result from the third clock cycle. In the example shown in FIG. 3, the result from the third clock cycle leads to a comparison that determines whether Vin′ is greater than or less than Vref×⅛. After the comparison in the fourth clock cycle, SAR ADC 115 determines the bit value for bit the LSB B0. After all four clock cycles, ADC 110 determines that the Code 9, which can be “1010”, is the correct digital representation of Vin′.

As a result of the redundancy performed by EC flash ADC 120 in the first clock cycle, the search range of all four clock cycles can remain within the range of −Vref to +Vref. Also, note that in the first clock cycle, the comparisons A and B can determine the bit value for the MSB with redundancy. If comparison B indicates that Vin′ is greater than −Vref/4 and the comparison A indicates that Vin′ is less than +Vref/4, then the redundant comparison can confirm that Vin′ is within the second voltage region from −Vref/4 to +Vref/4. If comparison B indicates that Vin′ is greater than −Vref/4 and the comparison A indicates that Vin′ is greater than +Vref/4, then the redundant comparison can confirm that Vin′ is within the third voltage region from Vref/4 to Vref. If comparison B indicates that Vin′ is less than −Vref/4 and the comparison A indicates that Vin′ is less than +Vref/4, then the redundant comparison can confirm that Vin′ is within the first voltage region from −Vref to −Vref/4. However, if comparison B indicates that Vin′ is less than −Vref/4 and the comparison A indicates that Vin′ is greater than +Vref/4, then there is an error since Vin′ cannot be both less than −Vref/4 and greater than +Vref/4.

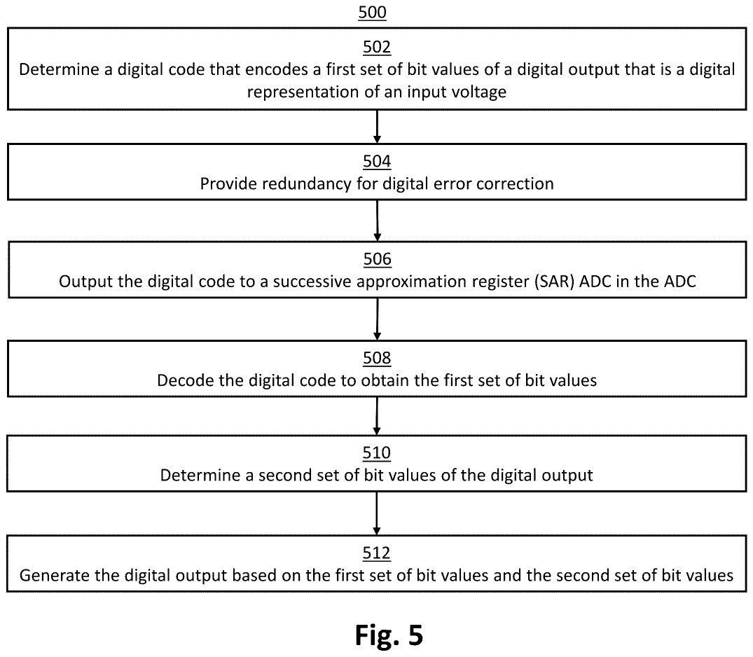

FIG. 5 is a flowchart of an example process that can implement flash successive approximation register analog-to-digital converter with error correction in one embodiment. Process 500 can include one or more operations, actions, or functions as illustrated by one or more of blocks 502, 504, 506, 508, 510 and/or 512. Although illustrated as discrete blocks, various blocks can be divided into additional blocks, combined into fewer blocks, eliminated, performed in different order, or performed in parallel, depending on the desired implementation.

Process 500 can be performed by a hybrid ADC, such as ADC 110 described in the present disclosure, to convert an analog signal into a digital signal. Process 500 can begin at block 502. At block 502, a flash ADC in the hybrid ADC can determine a digital code that encodes a first set of bit values of a digital output that is a digital representation of an input voltage. The digital output can include a set of most significant bits (MSBs) and a set of least significant bits (LSBs), and the first set of bit values can be bit values of the set of MSBs.

In one embodiment, the flash ADC can have a fractional bit resolution.

In one embodiment, the digital output can include N bits, the set of MSBs can include P bits, the set of LSBs can include Q bits, and a sum of P and Q is equivalent to N. In one embodiment, the digital output can include N bits, the set of MSBs can include one MSB, and the set of LSBs can include N−1 bits.

Process 500 can proceed from block 502 to block 504. At block 504, the flash ADC in the hybrid ADC can provide redundancy for digital error correction. In one embodiment, the flash ADC in the hybrid ADC can perform parallel comparison between the input voltage and two or more reference voltages to determine the digital code and to provide the redundancy for digital error correction in parallel, and encode comparison results of the parallel comparison to generate the digital code.

Process 500 can proceed from block 504 to block 506. At block 506, the flash ADC in the hybrid ADC can output the digital code to a successive approximation register (SAR) ADC in the hybrid ADC.

In one embodiment, the SAR ADC in the hybrid ADC can receive an analog signal, sample the analog signal to generate the input voltage, and send the input voltage to the flash ADC.

Process 500 can proceed from block 506 to block 508. At block 508, the SAR ADC in the hybrid ADC can decode the digital code to obtain the first set of bit values.

Process 500 can proceed from block 508 to block 510. At block 510, the SAR ADC in the hybrid ADC can determine a second set of bit values of the digital output. The second set of bit values can be bit values of the set of LSBs. In one embodiment, the flash ADC in the hybrid ADC can compare the input voltage with a first set of reference voltages comprising two or more reference voltages, and the SAR ADC in the hybrid ADC can compare the input voltage with a second set of reference voltages different from the first set of reference voltages.

Process 500 can proceed from block 510 to block 512. At block 512, the SAR ADC in the hybrid ADC can generate the digital output based on the first set of bit values and the second set of bit values.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be implemented substantially concurrently, or the blocks may sometimes be implemented in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

### EXAMPLES

Example 1: A semiconductor device comprising a successive approximation register (SAR) analog-to-digital converter (ADC); and a flash ADC with a fractional bit resolution, the flash ADC being configured to: determine a digital code that encodes a voltage range of an input voltage; provide redundancy for digital error correction; and output the digital code to the SAR ADC; the SAR ADC is configured to: decode the digital code to obtain a first set of bit values of a set of most significant bits (MSBs) of a digital output that is a digital representation of the input voltage; determine a second set of bit values of a set of least significant bits (LSBs) of the digital output; and generate the digital output based on the first set of bit values and the second set of bit values.

Example 2: The semiconductor device of Example 1, wherein: the digital output comprises N bits; the set of MSBs comprises P bits; the set of LSBs comprises Q bits; and a sum of P and Q is equivalent to N.

Example 3: The semiconductor device of any one of Examples 1 and 2, wherein: the digital output comprises N bits; the set of MSBs comprises one MSB; and the set of LSBs comprises N−1 bits.

Example 4: The semiconductor device of any one of Examples 1 to 3, wherein the SAR ADC comprises a sample and hold circuit configured to: receive an analog signal; sample the analog signal to generate the input voltage; and send the input voltage to the flash ADC.

Example 5: The semiconductor device of any one of Examples 1 to 4, wherein the flash ADC is configured to: perform parallel comparison between the input voltage and two or more reference voltages to determine the digital code and to provide the redundancy for digital error correction in parallel; and encode comparison results of the parallel comparison to generate the digital code.

Example 6: The semiconductor device of any one of Examples 1 to 5, wherein the SAR ADC comprises a digital-to-analog converter (DAC), and the DAC is configured to receive the digital code from the flash ADC.

Example 7: The semiconductor device of any one of Examples 1 to 6, wherein: the flash ADC is configured to compare the input voltage with a first set of reference voltages; and the SAR ADC is configured to compare the input voltage with a second set of reference voltages different from the first set of reference voltages.

Example 8: A system comprising: a first device configured to output an analog signal; a second device; and an analog-to-digital converter (ADC) comprising: a successive approximation register (SAR) ADC; and a flash ADC with a fractional bit resolution, the flash ADC being configured to: determine a digital code that encodes a voltage range of an input voltage sampled from the analog signal; provide redundancy for digital error correction; and output the digital code to the SAR ADC; the SAR ADC is configured to: decode the digital code to obtain a first set of bit values of a set of most significant bits (MSBs) of a digital output that is a digital representation of the input voltage; determine a second set of bit values of a set of least significant bits (LSBs) of the digital output; and generate the digital output based on the first set of bit values and the second set of bit values; and output the digital output to the second device.

Example 9: The system of Example 8, wherein: the digital output comprises N bits; the set of MSBs comprises P bits; the set of LSBs comprises Q bits; and a sum of P and Q is equivalent to N.

Example 10: The system of any one of Examples 8 and 9, wherein: the digital output comprises N bits; the set of MSBs comprises one MSB; and the set of LSBs comprises N−1 bits.

Example 11: The system of any one of Examples 8 to 10, wherein the flash ADC is configured to: perform parallel comparison between the input voltage and two or more reference voltages to determine the digital code and to provide the redundancy for digital error correction in parallel; and encode comparison results of the parallel comparison to generate the digital code.

Example 12: The system of any one of Examples 8 to 11, wherein the SAR ADC comprises a digital-to-analog converter (DAC), and the DAC is configured to receive the digital code from the flash ADC.

Example 13: The system of any one of Examples 8 to 12, wherein: the flash ADC is configured to compare the input voltage with a first set of reference voltages; and the SAR ADC is configured to compare the input voltage with a second set of reference voltages different from the first set of reference voltages.

Example 14: A method for converting an analog signal into a digital signal, the method comprising determining, by a flash analog-to-digital converter (ADC) in an ADC, a digital code that encodes a first set of bit values of a digital output that is a digital representation of an input voltage, wherein the digital output comprises a set of most significant bits (MSBs) and a set of least significant bits (LSBs), and the first set of bit values are bit values of the set of MSBs; providing, by the flash ADC in the ADC, redundancy for digital error correction; outputting, by the flash ADC in the ADC, the digital code to a successive approximation register (SAR) ADC in the ADC; decoding, by the SAR ADC in the ADC, the digital code to obtain the first set of bit values; determining, by the SAR ADC in the ADC, a second set of bit values of the digital output, wherein the second set of bit values are bit values of the set of LSBs; and generating, by the SAR ADC in the ADC, the digital output based on the first set of bit values and the second set of bit values.

Example 15: The method of Example 14, wherein the flash ADC has a fractional bit resolution.

Example 16: The method of any one of Examples 14 and 15, wherein: the digital output comprises N bits; the set of MSBs comprises P bits; the set of LSBs comprises Q bits; and a sum of P and Q is equivalent to N.

Example 17: The method of any one of Examples 14 to 16, wherein: the digital output comprises N bits; the set of MSBs comprises one MSB; and the set of LSBs comprises N−1 bits.

Example 18: The method of any one or Examples 14 to 17, further comprising: receiving, by the SAR ADC in the ADC, an analog signal; sampling, by the SAR ADC in the ADC, the analog signal to generate the input voltage; and sending, by the SAR ADC in the ADC, the input voltage to the flash ADC.

Example 19: The method of any one of Examples 14 to 18, further comprising: performing, by the flash ADC in the ADC, parallel comparison between the input voltage and two or more reference voltages to determine the digital code and to provide the redundancy for digital error correction in parallel; and encoding, by the flash ADC in the ADC, comparison results of the parallel comparison to generate the digital code.

Example 20: The method of any one of Examples 14 to 19, further comprising: comparing, by the flash ADC in the ADC, the input voltage with a first set of reference voltages comprising two or more reference voltages; and comparing, by the SAR ADC in the ADC, the input voltage with a second set of reference voltages different from the first set of reference voltages.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The disclosed embodiments of the present disclosure have been presented for purposes of illustration and description but are not intended to be exhaustive or limited to the present disclosure in the forms disclosed. Many modifications and variations will be apparent to those of ordinary skill in the art without departing from the scope and spirit of the present disclosure. The embodiments were chosen and described in order to best explain the principles of the present disclosure and the practical application, and to enable others of ordinary skill in the art to understand the present disclosure for various embodiments with various modifications as are suited to the particular use contemplated.

What is claimed is:

1. A semiconductor device comprising:
a successive approximation register (SAR) analog-to-digital converter (ADC); and
a flash ADC with a fractional bit resolution, the flash ADC being configured to:
determine a digital code that encodes a voltage range of an input voltage;
provide redundancy for digital error correction; and
output the digital code to the SAR ADC;
wherein the SAR ADC is configured to:
decode the digital code to obtain a first set of bit values of a set of most significant bits (MSBs) of a digital output that is a digital representation of the input voltage;
determine a second set of bit values of a set of least significant bits (LSBs) of the digital output; and
generate the digital output based on the first set of bit values and the second set of bit values.

2. The semiconductor device of claim 1, wherein:
the digital output comprises N bits;
the set of MSBs comprises P bits;
the set of LSBs comprises Q bits; and
a sum of P and Q is equivalent to N.

3. The semiconductor device of claim 1, wherein:
the digital output comprises N bits;
the set of MSBs comprises one MSB; and
the set of LSBs comprises N−1 bits.

4. The semiconductor device of claim 1, wherein the SAR ADC comprises a sample and hold circuit configured to:
receive an analog signal;
sample the analog signal to generate the input voltage; and
send the input voltage to the flash ADC.

5. The semiconductor device of claim 1, wherein the flash ADC is configured to:
perform parallel comparison between the input voltage and two or more reference voltages to determine the digital code and to provide the redundancy for digital error correction in parallel; and
encode comparison results of the parallel comparison to generate the digital code.

6. The semiconductor device of claim 1, wherein the SAR ADC comprises a digital-to-analog converter (DAC), and the DAC is configured to receive the digital code from the flash ADC.

7. The semiconductor device of claim 1, wherein:
the flash ADC is configured to compare the input voltage with a first set of reference voltages; and
the SAR ADC is configured to compare the input voltage with a second set of reference voltages different from the first set of reference voltages.

8. A system comprising:
a first device configured to output an analog signal;
a second device; and
an analog-to-digital converter (ADC) comprising:
a successive approximation register (SAR) ADC; and
a flash ADC with a fractional bit resolution, the flash ADC being configured to:
determine a digital code that encodes a voltage range of an input voltage sampled from the analog signal;
provide redundancy for digital error correction; and
output the digital code to the SAR ADC;
wherein the SAR ADC is configured to:
decode the digital code to obtain a first set of bit values of a set of most significant bits (MSBs) of a digital output that is a digital representation of the input voltage;
determine a second set of bit values of a set of least significant bits (LSBs) of the digital output; and
generate the digital output based on the first set of bit values and the second set of bit values; and
output the digital output to the second device.

9. The system of claim 8, wherein:
the digital output comprises N bits;
the set of MSBs comprises P bits;
the set of LSBs comprises Q bits; and
a sum of P and Q is equivalent to N.

10. The system of claim 8, wherein:
the digital output comprises N bits;
the set of MSBs comprises one MSB; and
the set of LSBs comprises N−1 bits.

11. The system of claim 8, wherein the flash ADC is configured to:
perform parallel comparison between the input voltage and two or more reference voltages to determine the digital code and to provide the redundancy for digital error correction in parallel; and
encode comparison results of the parallel comparison to generate the digital code.

12. The system of claim 8, wherein the SAR ADC comprises a digital-to-analog converter (DAC), and the DAC is configured to receive the digital code from the flash ADC.

13. The system of claim 8, wherein:
the flash ADC is configured to compare the input voltage with a first set of reference voltages; and
the SAR ADC is configured to compare the input voltage with a second set of reference voltages different from the first set of reference voltages.

14. A method for converting an analog signal into a digital signal, the method comprising:
determining, by a flash analog-to-digital converter (ADC) in an ADC, a digital code that encodes a first set of bit values of a digital output that is a digital representation of an input voltage, wherein the digital output comprises a set of most significant bits (MSBs) and a set of least significant bits (LSBs), and the first set of bit values are bit values of the set of MSBs;
providing, by the flash ADC in the ADC, redundancy for digital error correction;
outputting, by the flash ADC in the ADC, the digital code to a successive approximation register (SAR) ADC in the ADC;
decoding, by the SAR ADC in the ADC, the digital code to obtain the first set of bit values;
determining, by the SAR ADC in the ADC, a second set of bit values of the digital output, wherein the second set of bit values are bit values of the set of LSBs; and
generating, by the SAR ADC in the ADC, the digital output based on the first set of bit values and the second set of bit values.

15. The method of claim 14, wherein the flash ADC has a fractional bit resolution.

16. The method of claim 14, wherein:
the digital output comprises N bits;
the set of MSBs comprises P bits;
the set of LSBs comprises Q bits; and
a sum of P and Q is equivalent to N.

17. The method of claim 14, wherein:
the digital output comprises N bits;
the set of MSBs comprises one MSB; and
the set of LSBs comprises N−1 bits.

18. The method of claim 14, further comprising:
receiving, by the SAR ADC in the ADC, an analog signal;
sampling, by the SAR ADC in the ADC, the analog signal to generate the input voltage; and
sending, by the SAR ADC in the ADC, the input voltage to the flash ADC.

19. The method of claim 14, further comprising:
performing, by the flash ADC in the ADC, parallel comparison between the input voltage and two or more reference voltages to determine the digital code and to provide the redundancy for digital error correction in parallel; and
encoding, by the flash ADC in the ADC, comparison results of the parallel comparison to generate the digital code.

20. The method of claim 14, further comprising:
comparing, by the flash ADC in the ADC, the input voltage with a first set of reference voltages comprising two or more reference voltages; and
comparing, by the SAR ADC in the ADC, the input voltage with a second set of reference voltages different from the first set of reference voltages.
